(19) United States
(12) Patent Application Publication
(10) Pub. No.: US 2026/0188980 A1
(43) Pub. Date: Jul. 2, 2026

(54) VERTICAL LIGHT EMITTING NANOROD LASER DIODE AND METHOD OF THEREOF

(71) Applicant: INDUSTRIAL COOPERATION FOUNDATION JEONBUK NATIONAL UNIVERSITY, Jeonju-si (KR)

(72) Inventor: Yong Ho RA, Jeonju-si (KR)

(21) Appl. No.: 19/177,668

(22) Filed: Apr. 14, 2025

Related U.S. Application Data
(63) Continuation of application No. PCT/KR2023/014339, filed on Sep. 21, 2023.

(30) Foreign Application Priority Data
Oct. 20, 2022 (KR) 10-2022-0135801
Nov. 30, 2022 (KR) 10-2022-0163694
May 11, 2023 (KR) 10-2023-0061226

(51) Int. Cl. H01S 5/34

(52) U.S. Cl. CPC H01S 5/341; H01S 5/3416

(57) ABSTRACT

A vertical light-emitting nanorod laser diode and a method of manufacturing the vertical light-emitting nanorod laser diode are provided, and more specifically, a vertical light-emitting nanorod laser diode can vertically emit light without using a DBR by depositing a nitride-based nanorod LED structure as a thin film on a substrate and using the deposited nanorod LED structure itself as a light reflector for laser oscillation.

### TECHNICAL FIELD

### Research Project Information 1

Project unique number:
Project number: RS-2024-00404278
Ministry name: Ministry Of Science And ICT
Project management (specialized) organization name: Korea Basic Science Institute
Research business name: New Researcher Infrastructure Support Project
Research project name: Installation of Plasma-assisted Molecular Beam Epitaxy System for Hyper-nano-optical Semiconductors
Project execution organization name: Jeonbuk National University
Research period: 2024-05-01˜2025-04-30

### Research Project Information 2

Project unique number:
Project number: RS-2024-00358275
Ministry name: Ministry of Science and ICT
Project management (specialized) organization name: National Research Foundation of Korea
Research business name: Excellent New Research Project
Research project name: Development of Super-emission Non-polar Tunnel-junction Nanorod-LED Device Fabrication
Project executing organization name: Jeonbuk National University
Research period: 2024-04-01˜2027-03-31

### Research Project Information 3

Project unique number:
Project Number: RS-2024-00443714
Ministry name: Ministry of Education
Project management (specialized) organization name: National Research Foundation of Korea
Research business name: Global-Learning & Academic research institution for Master's·PhD students, and Postdocs(LAMP) Program (G-LAMP)
Research project name: Research on Deposition and Morphological Engineering of Hyper-Semiconductor Nanostructures
Project executing organization name: G-LAMP project group of Jeonbuk National University
Research period: 2024-09-01˜2029-08-31

The present invention relates to a vertical light-emitting nanorod laser diode and a method of manufacturing the vertical light-emitting nanorod laser diode, and more specifically, to a vertical light-emitting nanorod laser diode capable of vertically emitting light without using a DBR by depositing a nitride-based nanorod LED structure as a thin film on a substrate and using the deposited nanorod LED structure itself as a light reflector for laser oscillation.

### BACKGROUND ART

GaN, which is a nitride, has a bandgap energy of 3.39 eV and is a wide bandgap semiconductor of a direct transition type, and accordingly, GaN is a useful material for manufacturing light-emitting elements in a short wavelength range.

Efforts have been made to manufacture semiconductor lasers by using GaN since the past, and among semiconductor lasers, a semiconductor laser that emits laser in a direction perpendicular to an upper surface is called a vertical cavity semiconductor laser diode (VCSEL).

The vertical cavity surface-emitting laser (VCSEL) has been actively studied recently because VCSEL has an advantage that a length of a resonator that causes constructive interference to amplify the light is short.

A length of a resonator (cavity) is mostly between about 1 λ to several λ, and a distributed Bragg reflector (hereinafter referred to as DBR) with high reflectivity is required to emit light from such a short resonator.

Korean Patent Publication No. 10-2000-0046475 (published on Jul. 25, 2000), which is a conventional technology, proposes ‘DEVICE FOR GAN SHORTWAVE VERTICAL SURFACE EMITTING LASER DIODE AND METHOD THEREOF’ in which a dielectric DBR is formed on both an upper portion and a lower portion of a laser oscillation layer, and Korean Patent Publication No. 10-2017-0063919 (published on Jun. 9, 2017) proposes ‘A METHOD FOR GaN VERTICAL MICROCAVITY SURFACE EMITTING LASER (VCSEL)’.

However, although the conventional technologies have the disadvantage of using a complex structure of DBR (Distributed Bragg Reflector) at an upper portion and a lower portion although the DBR is a type of semiconductor laser diode that emits laser in a direction perpendicular to an upper surface.

Meanwhile, the existing nitride-based GaN LED or GaN LD (laser diode) structure is usually formed with a metal electrode, p-GaN, InGaN active layer, n-GaN, and metal electrode structure, but a junction of the metal electrode and p-GaN has the disadvantage of forming high resistance.

Also, with the daily use of mobile devices and the increase in personalized contents, innovative changes in the future display industry are expected, and in particular, with the emergence of metaverse concept, industrial demand for ultra-realistic display technology for maximizing immersion of AR, VR, MR, and XR is explosively increasing.

The AR, VR, MR, and XR display markets were grown by 57.79% in 2021 to reach USD 581.07 million from USD 2020, and is expected to grow to 46.06% in a compound annual growth rate (CAGR) by reaching USD 5.838 billion in 2027.

Hyper-realistic AR, VR, MR, and XR display technology requires high standards, such as high brightness, high linearity, high color purity light source, and ultra-fine pixels.

However, the existing DMD, LCoS, OLED, and so on do not meet the standards for outdoor AR projectors in terms of brightness, and micro LED, which is in the initial research stage, shows relatively high brightness, but the pixel implementation at a level of monochromatic light and the linearity of a light source are insufficient.

### DISCLOSURE OF INVENTION

### Technical Problem

In order to solve the problems of the conventional technology described above, the present invention provides a vertical light-emitting nanorod laser diode, which may vertically emit light without using a DBR by depositing a nitride-based nanorod LED structure on a substrate as a thin film and using the deposited nanorod LED structure as a light reflector for laser oscillation, and a method of manufacturing the vertical light-emitting nanorod laser diode.

### Solution to Problem

A vertical light-emitting nanorod laser diode according to the present invention includes a substrate including a plurality of nanoholes formed on an upper surface of the substrate; a plurality of nanorod LED structures having a structure in which thin films are respectively deposited on the plurality of nanoholes to have a set vertical length, and a quantum well active layer, a p-GaN layer, and a tunnel junction layer are provided between a lower n-GaN layer and an upper n-GaN layer; a passivation layer including a passivation material applied on an upper surface of the substrate to have a thickness capable of covering entirety of the plurality of nanorod LED structures, and having an upper portion etched to expose a part of the upper n-GaN layer; a lower metal electrode layer deposited on a lower surface of the substrate; and an ohmic metal electrode layer deposited on an upper surface of the passivation layer in which a part of the upper n-GaN layer is exposed, wherein the tunnel junction layer is formed of one of Al, Au, In, Ga, MoS₂, graphene, AlN, InGaN, AlGaN, AlInGaN, and GaN.

Also, the vertical light-emitting nanorod laser diode according to the present invention further includes an indium tin oxide (ITO)-based transparent electrode ITO layer configured to replace the ohmic metal electrode layer or deposited on an upper portion of the ohmic metal electrode layer; and an upper metal window electrode layer in which a window penetrated vertically is formed in a preset shape, a metal is deposited on a side end of the window, and the window is placed on an upper portion of the ohmic metal electrode layer or the transparent electrode ITO layer.

Here, each of the plurality of nanorod LED structures has a structure in which the lower n-GaN layer, the quantum well active layer, the p-GaN layer, a p⁺-GaN layer, the tunnel junction layer, an n⁺-GaN layer, and the upper n-GaN layer are sequentially stacked; a structure in which the lower n-GaN layer, the quantum well active layer, the p-GaN layer, the tunnel junction layer, and the upper n-GaN layer are sequentially stacked; a structure in which the lower n-GaN layer, the tunnel junction layer, the p-GaN layer, the quantum well active layer, and the upper n-GaN layer are sequentially stacked; or a structure in which the lower n-GaN layer, the p⁺-GaN layer, the tunnel junction layer, the n⁺-GaN layer, the p-GaN layer, the quantum well active layer, and the upper n-GaN layer are sequentially stacked.

Here, the quantum well active layer has a structure in which a first nitride and a second nitride that are different from each other are interchangeably stacked in multiple layers, the first nitride is formed of one of GaN, InN, AlGaN, AlInGaN, and AlN, and the second nitride is formed of one of InGaN, InN, AlGaN, AlInGaN, GaN, and AlN.

Also, in the vertical light-emitting nanorod laser diode according to the present invention, a full width at half maximum (FWHM) of an emission wavelength and a wavelength position are adjusted by changing cross-sectional shapes and cross-sectional sizes of the plurality of nanorod LED structures deposited respectively in the plurality of nanoholes as thin films and intervals between the plurality of nanorod LED structures through changes in shapes, sizes, and arrangement patterns of the plurality of nanoholes.

Also, a method of manufacturing a vertical light-emitting nanorod laser diode includes a nanohole patterning step of depositing a mask layer on an upper portion of a substrate, depositing a photoresist on the mask layer, and forming a plurality of nanoholes to have a preset shape, a preset size, and a preset pattern; a nanorod forming step of depositing thin films respectively in the plurality of nanoholes to have a preset length in a vertical direction and forming a plurality of nanorod LED structures, each having a structure including a quantum well active layer, a p-GaN layer, and a tunnel junction layer between a lower n-GaN layer and an upper n-GaN layer; a passivation layer forming step of forming a passivation layer by applying a passivation material on the upper portion of the substrate to have a thickness capable of covering entirety of the plurality of nanorod LED structures; a passivation layer etching step of etching an upper portion of the passivation layer to expose a part of the upper n-GaN layer above the passivation layer; a lower metal electrode layer depositing step of depositing a lower metal electrode layer on a lower surface of the substrate; and an ohmic metal electrode layer depositing step of depositing an ohmic metal electrode on an upper surface of the passivation layer, in which a part of the upper n-GaN layer is exposed, wherein the tunnel junction layer in the nanorod forming step is formed of one of Al, Au, In, Ga, MoS₂, graphene, AlN, InGaN, AlGaN, AlInGaN, and GaN.

Also, the method of manufacturing a vertical light-emitting nanorod laser diode further includes a transparent electrode ITO layer depositing step of replacing the ohmic metal electrode layer or depositing an indium tin oxide (ITO)-based transparent electrode ITO layer on an upper portion of the ohmic metal electrode layer; and an upper metal window electrode layer depositing step of depositing an upper metal window electrode layer in which a window penetrated vertically is formed in a preset shape and metal is deposited on a side end of the window such that the window is placed on an upper portion of the ohmic metal electrode layer or the transparent electrode ITO layer.

### Advantageous Effects of Invention

According to the configuration described above, a vertical light-emitting nanorod laser diode and a method of manufacturing the same according to the present invention have an advantage in that light may be emitted vertically without using a relatively large DBR having relatively large volume, process steps are reduced and simplified by removing the DBR, which not only reduces a process cost but also enables production in an ultra-small structure, and when a current is injected, the DBR that hinders a current flow is removed, which reduces resistance and increases a light generation efficiency.

Also, the vertical light-emitting nanorod laser diode and the method of manufacturing the same according to the present invention have an advantage in that an n-GaN layer may be placed on both an upper portion and a lower portion of a nanorod LED structure coupled to a metal electrode by providing a tunnel junction layer in the nanorod LED structure, resulting in relatively low resistivity compared to coupling between a conventional p-GaN layer and a metal electrode, thereby improving a current injection and an efficiency of a laser diode.

Also, the vertical light-emitting nanorod laser diode and the method of manufacturing the same according to the present invention have an advantage in that a full width at half maximum (FWHM) of an emission wavelength and a wavelength position may be adjusted by changing cross-sectional shapes and cross-sectional sizes of nanorod LED structures deposited respectively in nanoholes formed in a substrate as thin films and changing an interval between the nanorod LED structures.

Also, the vertical light-emitting nanorod laser diode and the method of manufacturing the same according to the present invention have an advantage in that it is possible to implement display pixels with high linearity through fusion with a micro LED technology and so on.

### BRIEF DESCRIPTION OF DRAWINGS

FIG. 1 is a perspective view of a vertical light-emitting nanorod laser diode according to an embodiment of the present invention.

FIG. 2 is a perspective view of a substrate according to an embodiment of the present invention.

FIGS. 3A-3D are plan views illustrating a state in which nanoholes having various shapes, sizes, and arrangement patterns are formed on a substrate, according to an embodiment of the present invention.

FIG. 4 is a perspective view illustrating a state in which a plurality of nanorod LED structures are deposited on a substrate as thin films, according to an embodiment of the present invention.

FIGS. 5A-5D are perspective views illustrating various stacking structures of nanorod LED structures according to an embodiment of the present invention.

FIGS. 6A-6G illustrate use state views showing a sequential growth and a stack order of a nanorod LED structure according to an embodiment of the present invention.

FIG. 7 is a conceptual view illustrating a state in which a laser is vertically emitted through a nanorod LED structure according to an embodiment of the present invention.

FIGS. 8A-8C illustrate example views of nanorod LED structures formed to correspond to various shapes, sizes, and arrangement patterns of nanoholes formed in a substrate, according to an embodiment of the present invention.

FIGS. 9A-9B illustrate use state views showing formation and etching state of a passivation layer according to an embodiment of the present invention.

FIG. 10 is a perspective view illustrating a state in which a lower metal electrode layer and an ohmic metal electrode layer are deposited according to an embodiment of the present invention.

FIGS. 11A-11C illustrate perspective views of various stack combinations of an ohmic metal electrode layer, a transparent electrode ITO layer, and an upper metal window electrode layer, according to an embodiment of the present invention.

FIG. 12 is an optical microscope measurement image of an optical device manufactured by a vertical light-emitting nanorod laser diode according to an embodiment of the present invention.

FIG. 13 is a graph illustrating a result of measuring a current and a voltage of a vertical light-emitting nanorod laser diode according to an embodiment of the present invention.

FIG. 14 is a graph illustrating a result of measuring electroluminescence of a vertical light-emitting nanorod laser diode according to an embodiment of the present invention.

FIG. 15 is a graph illustrating efficiency degradation characteristics according to a heat emission effect of a vertical light-emitting nanorod laser diode according to an embodiment of the present invention.

FIG. 16 is an image of a result of simulating FDTD of a vertical light-emitting nanorod laser diode according to an embodiment of the present invention.

FIG. 17 is a flowchart of a method of manufacturing a vertical light-emitting nanorod laser diode, according to an embodiment of the present invention.

### BEST MODE FOR CARRYING OUT THE INVENTION

A vertical light-emitting nanorod laser diode according to the present invention includes a substrate including a plurality of nanoholes formed on an upper surface of the substrate; a plurality of nanorod LED structures having a structure in which thin films are respectively deposited on the plurality of nanoholes to have a set vertical length, and a quantum well active layer, a p-GaN layer, and a tunnel junction layer are provided between a lower n-GaN layer and an upper n-GaN layer; a passivation layer including a passivation material applied on an upper surface of the substrate to have a thickness capable of covering entirety of the plurality of nanorod LED structures, and having an upper portion etched to expose a part of the upper n-GaN layer; a lower metal electrode layer deposited on a lower surface of the substrate; and an ohmic metal electrode layer deposited on an upper surface of the passivation layer in which a part of the upper n-GaN layer is exposed, wherein the tunnel junction layer is formed of one of Al, Au, In, Ga, MoS₂, graphene, AlN, InGaN, AlGaN, AlInGaN, and GaN.

### Mode for the Invention

Hereinafter, a vertical light-emitting nanorod laser diode according to the present invention will be described in more detail with reference to embodiments illustrated in the drawings.

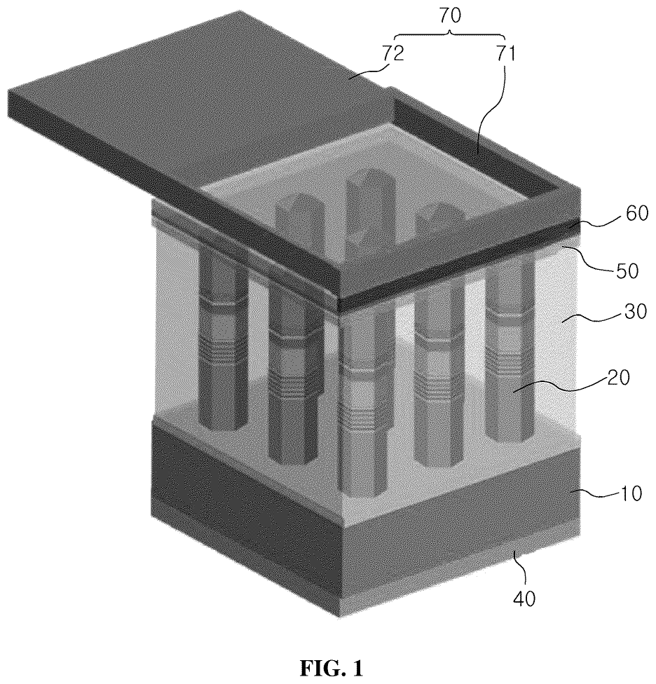

FIG. 1 is a perspective view of a vertical light-emitting nanorod laser diode according to an embodiment of the present invention.

Referring to FIG. 1, the vertical light-emitting nanorod laser diode according to the embodiment of the present invention includes a substrate 10, a plurality of nanorod LED structures 20, a passivation layer 30, a lower metal electrode layer 40, an ohmic metal electrode layer 50, a transparent electrode ITO layer 60, and an upper metal window electrode layer 70.

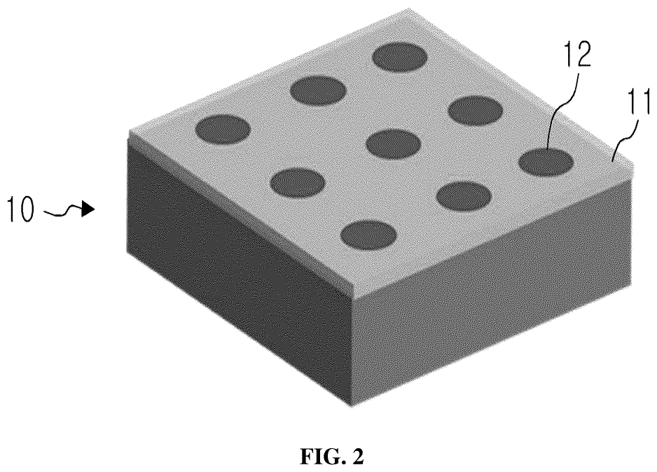

As illustrated in FIG. 2, the substrate 10 has a configuration in which a plurality of nanoholes 12 are formed in an upper surface.

In one embodiment of the present invention, the substrate 10 may be formed of silicon (Si), sapphire (Al₂O₃), glass, silicon carbide (SIC), gallium oxide (Ga₂O₃), gallium nitride (GaN), GaN on sapphire, InGaN on sapphire, AlGaN on sapphire, or AlN on sapphire.

A method of forming the nanohole 12 includes depositing first a mask layer 11 on an upper portion of the substrate 10.

The mask layer 11 may be deposited by various deposition equipment or methods, for example, sputtering, E-Beam vacuum deposition, atomic layer deposition, plasma enhanced chemical vapor deposition, molecular beam epitaxy, and metal organic chemical vapor deposition.

A material of the mask layer 11 may be an amorphous material, such as SiOx or SiNx, or a metal material, such as Al, Ni, Ti, or Mo, and a thickness of the mask layer 11 may be 0.01 to 200 nm (nanometers).

Thereafter, a photoresist (not illustrated) may be deposited on the mask layer 11, and then the plurality of nanoholes 12 may be formed in a preset shape, size, and pattern.

As equipment or methods used to form the nanohole 12, a photomask, electron-beam lithography, etching, nanoimprinting, a krypton fluoride (KrF) scanner, an argon fluoride (ArF) scanner, and an extreme ultraviolet (EUV) lithography method may be used.

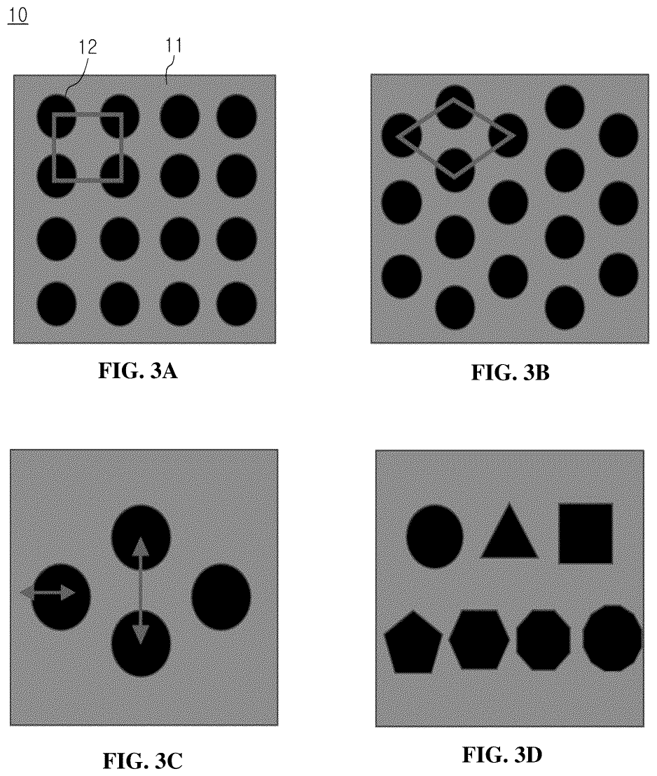

In one embodiment of the present invention, the nanoholes 12 may be formed in various shapes, sizes, and arrangement patterns as illustrated in FIGS. 3A-3D.

FIG. 3A illustrates a state where the nanoholes 12 are arranged in a square pattern, FIG. 3B illustrates a state where the nanoholes 12 are arranged in a rhombus pattern, FIG. 3C illustrates that an interval between the nanoholes 12 and diameters of the nanoholes 12 may be different from each other, and FIG. 3D illustrates that the nanoholes 12 may be formed in various shapes.

That is, a shape of the nanohole 12 may be a circle, a triangle, a square, a triangle, a pentagon, a hexagon, an octagon, a dodecagon, or so on, and a size of the nanohole 12 may be 20 nm (nanometer) to 1 um (micrometer).

Meanwhile, an arrangement pattern of the nanoholes 12 may be a square, a triangle, and a rhombus, and an interval between the nanoholes 12 may be from 50 nm to 2000 nm, and a diameter of the nanohole 12 may be from 10 nm to 1500 nm.

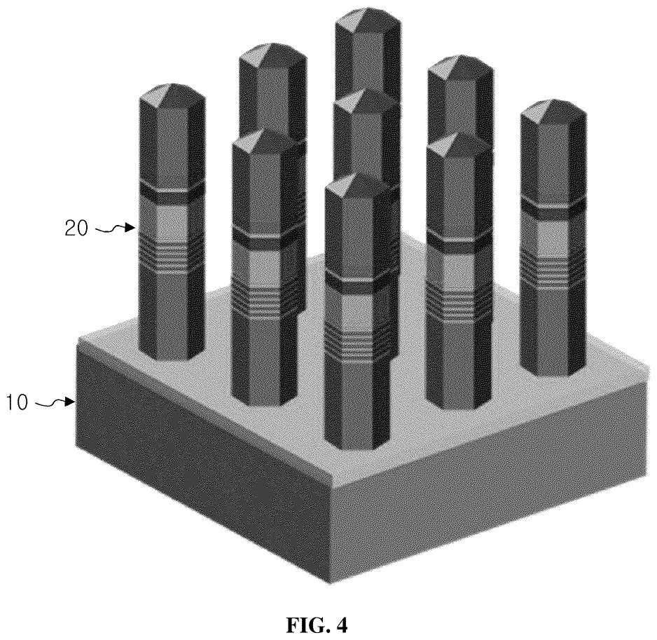

A plurality of nanorod LED structures 20 are deposited respectively in the plurality of nanoholes 12 as thin films to have a certain vertical length as illustrated in FIG. 4.

Here, the substrate 10 may be a silicon (Si) substrate, and at this time, a surface crystal direction of the substrate 10 may be (100), (110), (111), (001), (011), or so on.

Also, the substrate 10 may be any type of semiconductor substrate, such as a sapphir substrate, a GaN substrate, an AlN substrate, or a SiC substrate, and at this time, a surface crystal direction of the substrate 10 may be (100), (110), (111), (001), (011), or so on.

A deposition equipment for depositing the nanorod LED structure 20 as a thin film may be not only a molecular beam epitaxy equipment, but also a metal organic chemical vapor deposition equipment, a hydride vapor phase epitaxy (HVPE) equipment, a metal-organic vapor phase epitaxy (MOVPE) equipment, and a liquid phase epitaxy (LPE) deposition equipment.

Meanwhile, in one embodiment of the present invention, the nanorod LED structure 20 has a structure including a quantum well active layer, a p-GaN layer, and a tunnel junction layer between a lower n-GaN layer and an upper n-GaN layer.

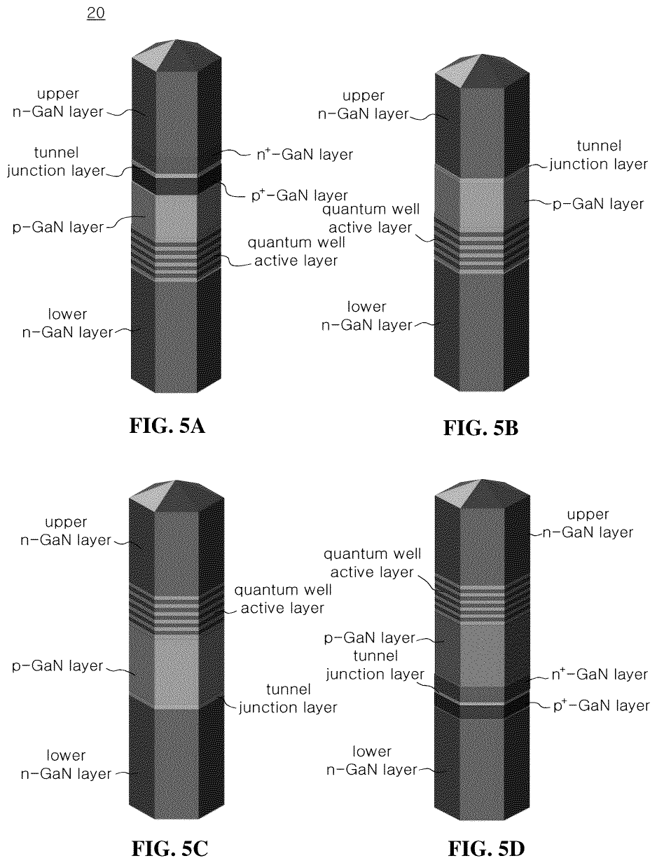

FIGS. 5A-5D illustrate various stacking structures of the nanorod LED structure 20 according to an embodiment of the present invention.

Referring to FIG. 5A, the nanorod LED structure 20 may have a structure in which a lower n-GaN layer, a quantum well active layer, a p-GaN layer, a p⁺-GaN layer, a tunnel junction layer, an n⁺-GanN layer, and an upper n-GaN layer are sequentially stacked.

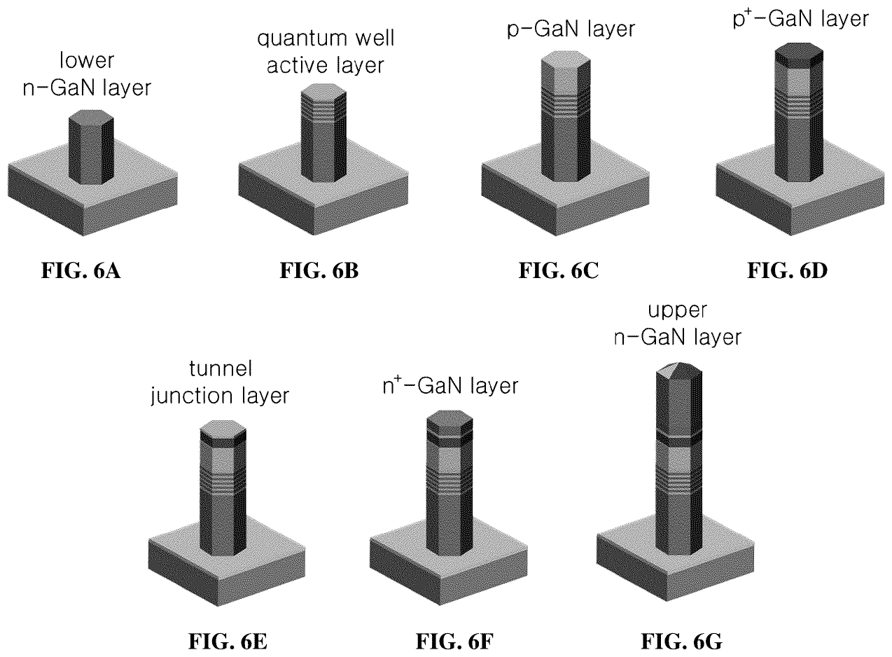

FIGS. 6A-6G illustrate a growth and sequential stacking order of the nanorod LED structure 20 having the structure of FIG. 5A.

A lower n-GaN layer illustrated in FIG. 6A is doped with Si for an n-type semiconductor, and the doping concentration of carriers may be 10^{3˜25}/cm⁻³, a substrate growth temperature may be 300 to 1200° C., and a nanorod length may be 10 nm to 100,000 nm.

A quantum well active layer illustrated in FIG. 6B has a structure in which a first nitride and a second nitride, which are different from each other, are alternately stacked in multiple layers.

Here, the first nitride may be any one of GaN, InN, AlGaN, AlInGaN, and AlN, and the second nitride may be any one of InGaN, InN, AlGaN, AlInGaN, GaN, and AlN.

The number of stacked quantum well active layers may be 1 to 200 arrays, a thickness of each layer may be 0.01 nm to 500 nm, and a substrate growth temperature may be 400 to 1200° C.

A p-GaN layer illustrated in FIG. 6C is doped with Mg for a p-type semiconductor, a carrier doping concentration may be 10^{3˜25}/cm⁻³, a substrate growth temperature may be 400 to 1200° C., and a nanorod length may be 10 nm to 100,000 nm.

A p⁺-GaN layer illustrated in FIG. 6D is heavily doped with Mg for a high-concentration p-type semiconductor, a carrier doping concentration may be 10^{15˜30}/cm⁻³, a substrate growth temperature may be 400 to 1200° C., and a nanorod length may be 1 nm to 100,000 nm.

A tunnel junction layer illustrated in FIG. 6E has a tunnel junction structure for a tunneling effect and may be formed of any one of Al, Au, In, Ga, MoS₂, graphene, AlN, InGaN, AlGaN, AlInGaN, and GaN.

A substrate growth temperature of the tunnel junction layer may be 400 to 1200° C., and a thickness of the layer may be 0.1 nm to 500 nm.

The present invention utilizes a tunneling effect of the tunnel junction layer as described above to enable an n-GaN layer (a lower n-GaN layer and an upper n-GaN layer) to be placed on both an upper portion and a lower portion of the nanorod LED structure 20, and accordingly, a relatively low resistivity compared to a junction between the existing p-GaN layer and a metal electrode may be obtained, causing a current injection to be improved, and thereby, the efficiency of a laser diode may be improved.

An n⁺-GanN layer illustrated in FIG. 6F is heavily doped with Si for a high-concentration n-type semiconductor, a carrier doping concentration may be 10^{15˜30}/cm⁻³, a substrate growth temperature may be 400 to 1200° C., and a nanorod length may be 1 nm to 100,000 nm.

An upper n-GaN layer illustrated in FIG. 6G is doped with Si for an n-type semiconductor, a substrate growth temperature may be 300 to 1200° C., a carrier doping concentration may be 10^{5˜25}/cm⁻³, and a nanorod length may be 10 nm to 100,000 nm.

Also, referring to FIG. 5B, the nanorod LED structure 20 may have a structure in which a lower n-GaN layer, a quantum well active layer, a p-GaN layer, a tunnel junction layer, and an upper n-GaN layer are sequentially stacked.

Also, referring to FIG. 5C, the nanorod LED structure 20 may have a structure in which a lower n-GaN layer, a tunnel junction layer, a p-GaN layer, a quantum well active layer, and an upper n-GaN layer are sequentially stacked.

Also, referring to FIG. 5D, the nanorod LED structure 20 may have a structure in which a lower n-GaN layer, a p⁺-GaN layer, a tunnel junction layer, an n⁺-GaN layer, a p-GaN layer, a quantum well active layer, and an upper n-GaN layer are sequentially stacked.

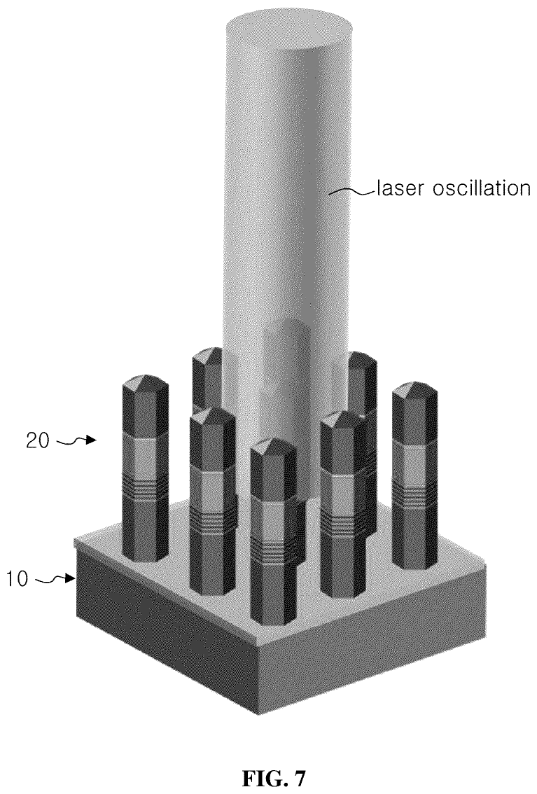

FIG. 7 illustrates a state in which a laser vertically oscillates through the plurality of nanorod LED structures 20, and a laser oscillation principle is that a photonic crystal effect occurs depending on an interval and length between the plurality of nanorod LED structures 20 to confine light for driving a laser and light is vertically emitted as the plurality of nanorod LED structures 20 act as reflectors.

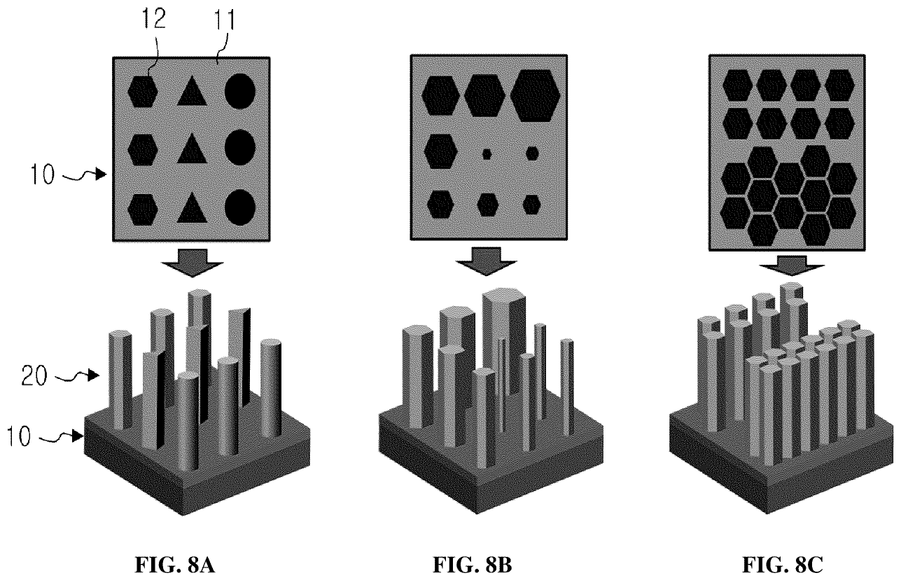

FIGS. 8A-8C illustrate states in which the nanorod LED structures 20 are formed to correspond to various shapes, sizes, and arrangement patterns of the nanoholes 12 formed on the substrate 10.

That is, in the present invention, as illustrated in FIGS. 8A-8C, cross-sectional shapes and cross-sectional sizes of the nanorod LED structures 20 deposited respectively in the nanoholes 12 as thin films, and intervals between the nanorod LED structures 20 may be changed through changes in shapes, sizes and arrangement patterns of the nanoholes 12, and accordingly, a full width at half maximum (FWHM) of an emission wavelength and a wavelength position may be adjusted.

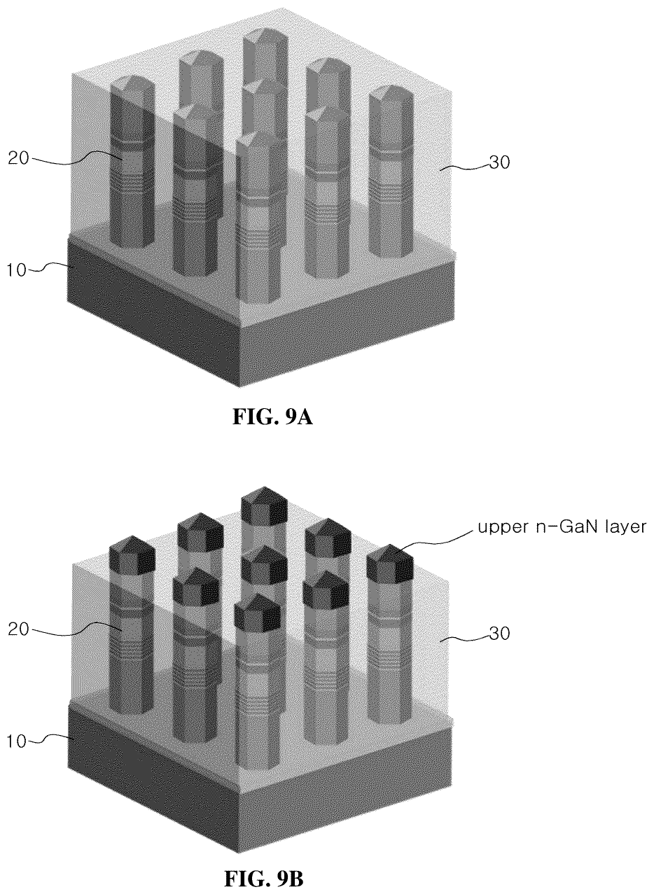

The passivation layer 30 is coated with a passivation material on an upper portion of the substrate 10 with a thickness that may cover the entirety of the plurality of nanorod LED structures 20, as illustrated in FIG. 9A, but has a configuration in which the upper portion is formed by being etched such that a part of the upper n-GaN layer may be exposed, as illustrated in FIG. 9B.

Here, the passivation material to be coated may be polysilazane, glass, or polyimide.

In one embodiment of the present invention, polyimide serving as the passivation material may be applied and deposited by a spin coater, and a speed of the spin coater may be 10 to 500 rpm.

A coating thickness of the passivation layer 30 may vary from 10 nm to 10 μm depending on lengths of the nanorod LED structures 20.

After the coating of the passivation layer 30 is completed, soft baking is performed, and a temperature of the soft baking may be 10 to 250° C., and the time may vary from 10 seconds to 1 hour.

For example, the soft baking may be performed at a temperature of about 120° C. for 3 minutes.

Also, the passivation layer 30 formed to have a thickness capable of covering all the plurality of nanorod LED structures 20 described above is etched at an upper portion such that a part of the upper n-GaN layer may be exposed, as illustrated in FIG. 9B.

The important point here is that the exposed layer has to be limited to only the upper n-GaN layer.

This is because a leakage current is generated when a quantum well active layer or tunnel junction layer is exposed.

Also, the reason for exposing a part of the upper n-GaN layer above the passivation layer 30 is to make an ohmic contact with the ohmic metal electrode layer 50 described below.

A thickness (length) of the upper n-GaN layer exposed above through an etching operation of the passivation layer 30 may vary from 5 nm to 5 um.

After the etching operation of the passivation layer 30 described above is completed, hard-baking is performed, and a temperature of the hard-baking may be 100 to 600° C., and the time may be from 30 seconds to 3 hours.

For example, the hard-baking may be performed at a temperature of about 250° C. for 30 minutes.

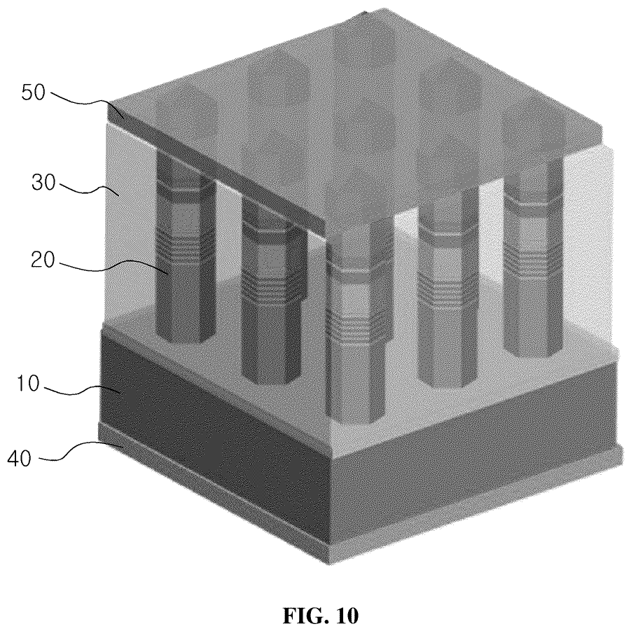

The lower metal electrode layer 40 is deposited on a lower surface of the substrate 10 as illustrated in FIG. 10 for n-type current injection.

The ohmic metal electrode layer 50 is deposited on an upper surface of the passivation layer 30 where a part of the upper n-GaN layer is exposed for n-type current injection as illustrated in FIG. 10.

The lower metal electrode layer 40 and the ohmic metal electrode layer 50 are each composed of two layers in usual, and Au is used for the first layer and Ni is used for the second layer, or Au may be used for the first layer and Ti may be used for the second layer, but metals, such as, Al, Au, Ag, In, Fe, Mo, Pt, Ni, and Ti, may be used for the respective layers and may also be used interchangeably.

A thickness of each of the lower metal electrode layer 40 and the ohmic metal electrode layer 50 may be varied from 1 nm to 1 um, and in general, the equipment used for deposition may be an E-beam evaporator or a sputtering equipment, but any equipment capable of depositing metal may be used therefor.

As described above, as the lower metal electrode layer 40 and the ohmic metal electrode layer 50 are deposited vertically, the nanorod LED structure layers 20 may emit light.

The transparent electrode ITO layer 60 is a layer that may replace the ohmic metal electrode layer 50 or be formed of indium tin oxide (ITO) deposited on an upper portion of the ohmic metal electrode layer 50 to uniformly distribute a current.

The upper metal window electrode layer 70 has a structure in which a window 71 is formed to have a preset shape that is penetrated vertically to enable light to be emitted to an upper portion of the nanorod LED structure layer 20, a metal 72 is deposited on a side end of the window 71, and the window 71 portion is deposited on an upper portion of the ohmic metal electrode layer 50 or the transparent electrode ITO layer 60.

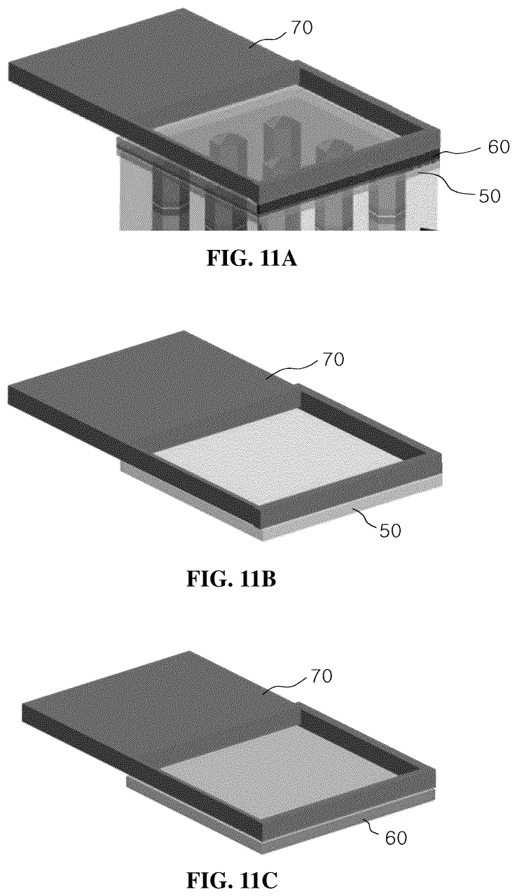

A shape of the window 71 formed on the upper metal window electrode layer 70 may be a square shape as illustrated in FIGS. 11A-11C, as well as a circle, a triangle, a hexagon, an octagon, or so on, in order to improve efficiency of the emitted light.

The upper metal window electrode layer 70 is usually composed of two layers, Au is used for a first layer and Ni is used for a second layer, or Au may be used for the first layer and Ti may be used for the second layer, but metals, such as, Al, Au, Ag, In, Fe, Mo, Pt, Ni, and Ti, may be used for the respective layers and may be used interchangeably.

In addition, instead of a total of two layers, 1 to 10 multi-layers may be user.

In a relationship between the ohmic metal electrode layer 50, the transparent electrode ITO layer 60, and the upper metal window electrode layer 70, the ohmic metal electrode layer 50, the transparent electrode ITO layer 60, and the upper metal window electrode layer 70 may be sequentially stacked and deposited as illustrated in FIG. 11A.

Meanwhile, in order to improve efficiency of the light emitted from the upper metal window electrode layer 70, the upper metal window electrode layer 70 may also be deposited in a structure in which either the ohmic metal electrode layer 50 or the transparent electrode ITO layer 60 is removed.

That is, as illustrated in FIG. 11B, the upper metal window electrode layer 70 may be deposited on the ohmic metal electrode layer 50 in a state where the transparent electrode ITO layer is removed, and as illustrated in FIG. 11C, the upper metal window electrode layer 70 may be deposited on the transparent electrode ITO layer 60 in a state where the ohmic metal electrode layer is removed.

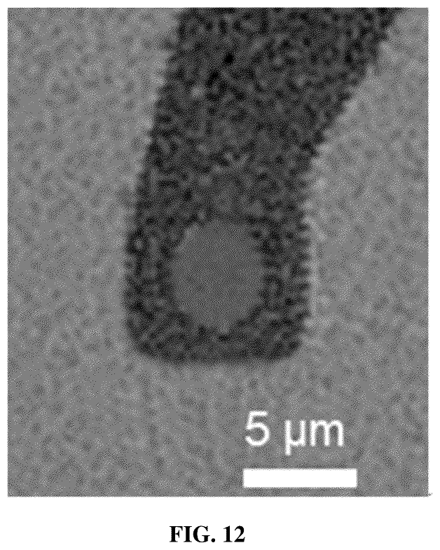

FIG. 12 is an optical microscope measurement image of an optical device manufactured by a vertical light-emitting nanorod laser diode according to an embodiment of the present invention.

Referring to FIG. 12, it can be seen that the vertical light-emitting nanorod laser diode according to the embodiment of the present invention includes the upper light-emitting window layer having a diameter of 5 μm or less.

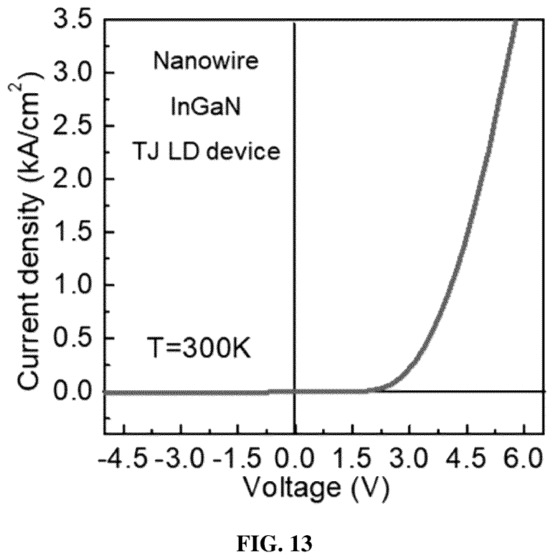

FIG. 13 is a graph illustrating a result of measuring a current and a voltage of a vertical light-emitting nanorod laser diode according to an embodiment of the present invention.

Referring to FIG. 13, it can be seen that a vertical light-emitting nanorod laser diode according to an embodiment of the present invention has a threshold voltage of 2.49 V at which light is emitted.

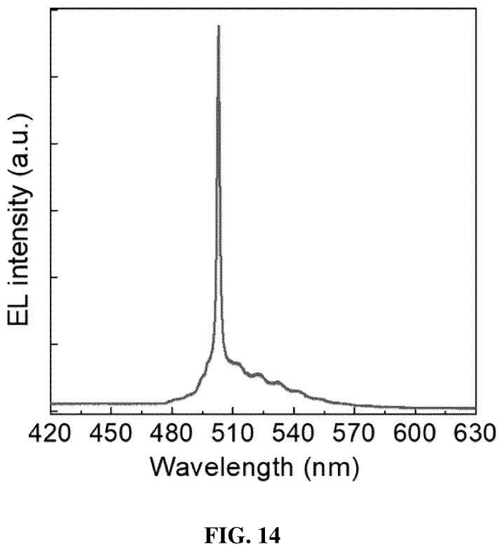

FIG. 14 is a graph illustrating a result of measuring electroluminescence of a vertical light-emitting nanorod laser diode according to an embodiment of the present invention.

Referring to FIG. 14, it can be seen that the vertical light-emitting nanorod laser diode according to the embodiment of the present invention emits vertical light having an emission center wavelength of 502.2 nm and a full width at half maximum (FWHM) of 0.98 nm.

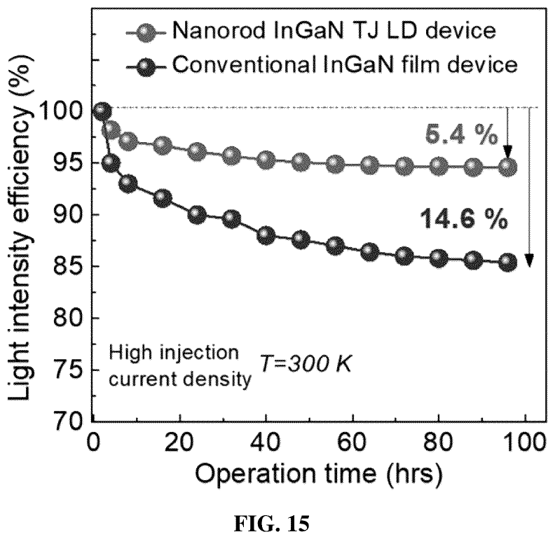

FIG. 15 is a graph illustrating efficiency degradation characteristics according to a heat emission effect of the vertical light-emitting nanorod laser diode according to the embodiment of the present invention.

Referring to FIG. 15, it can be seen that the vertical light-emitting nanorod laser diode according to the embodiment of the present invention has a luminous efficiency degradation rate of 5.4 % for a long operation time.

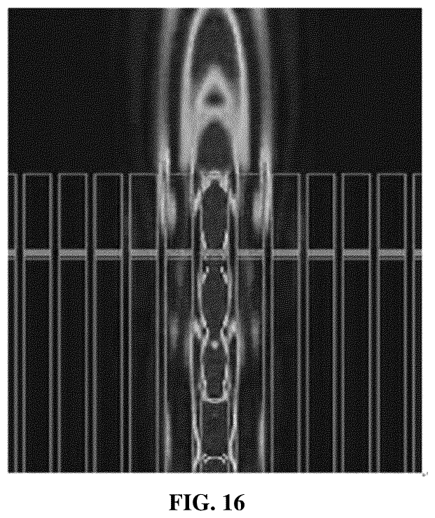

FIG. 16 is an image of a result of simulating FDTD of the vertical light-emitting nanorod laser diode according to the embodiment of the present invention.

Referring to FIG. 16, it can be seen that a photonic crystal effect of the vertical light-emitting nanorod laser diode according to the embodiment of the present invention is proven and that vertical light is emitted therefrom.

As described above, a vertical light-emitting nanorod laser diode according to an embodiment of the present invention is described, and hereinafter, a method of manufacturing the vertical light-emitting nanorod laser diode, according to an embodiment of the present invention, will be described with reference to the drawings.

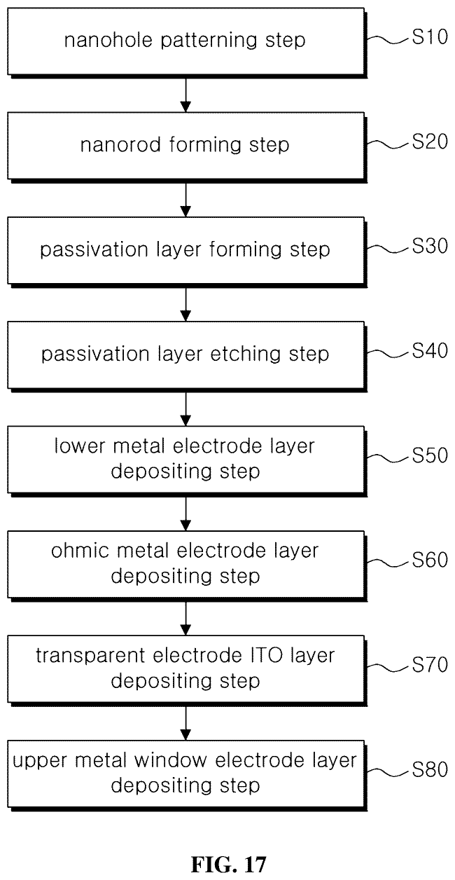

FIG. 17 is a flowchart illustrating a method of manufacturing a vertical light-emitting nanorod laser diode, according to an embodiment of the present invention.

Referring to FIG. 17, a method of manufacturing a vertical light-emitting nanorod laser diode according to an embodiment of the present invention includes a nanohole patterning step S10, a nanorod forming step S20, a passivation layer forming step S30, a passivation layer etching step S40, a lower metal electrode layer depositing step S50, an ohmic metal electrode layer depositing step S60, a transparent electrode ITO layer depositing step S70, and an upper metal window electrode layer depositing step S80.

Because specific components constituting the vertical light-emitting nanorod laser diode included in each step are described above, detailed descriptions thereof are omitted, and hereinafter, a flowchart of the method of manufacturing the vertical light-emitting nanorod laser diode, according to the embodiment of the present invention is described in detail.

The nanohole patterning step S10 is a step of depositing the mask layer 11 on an upper portion of the substrate 10, depositing a photoresist on the mask layer 11, and forming the plurality of nanoholes 12 having a preset shape, size, and pattern as illustrated in FIGS. 2 and 3.

The nanorod forming step S20 is a step of vertically depositing thin films respectively in the plurality of nanoholes 12 to have a preset length as illustrated in FIGS. 4 to 8, and forming the plurality of nanorod LED structures 20, each having a structure including a quantum well active layer, a p-GaN layer, and a tunnel junction layer provided between a lower n-GaN layer and an upper n-GaN layer.

The passivation layer forming step S30 is a step of forming the passivation layer 30 by coating an upper portion of the substrate 10 with a passivation material, such as polyimide to have a thickness that may cover the entirety of the plurality of nanorod LED structures 20, as illustrated in FIG. 9A.

The passivation layer etching step S40 is a step of etching an upper portion of the passivation layer 30 as illustrated in FIG. 9B to expose a part of the upper n-GaN layer above the upper portion of the passivation layer 30.

The lower metal electrode layer depositing step S50 is a step of depositing the lower metal electrode layer 40 on a lower surface of the substrate 10 as illustrated in FIG. 10.

The ohmic metal electrode layer depositing step S60 is a step of depositing the ohmic metal electrode layer 50 illustrated in FIG. 10 on an upper surface of the passivation layer 30 in which a part of the upper n-GaN layer is exposed, as illustrated in FIG. 9B.

The transparent electrode ITO layer depositing step S70 is a step of replacing the ohmic metal electrode layer 50 as illustrated in FIGS. 11A-11C, or depositing an indium tin oxide (ITO)-based transparent electrode ITO layer 60 on an upper portion of the ohmic metal electrode layer 50.

The upper metal window electrode layer deposition step S80 is a step of forming the window 71, which is penetrated vertically, in a preset shape, and depositing the upper metal window electrode layer 70 including the window 71 having a side end, in which the metal 72 is deposited, on an upper portion of the ohmic metal electrode layer 50 or the transparent electrode ITO layer 60 such that the window 71 portion is placed on the upper portion of the ohmic metal electrode layer 50 or the transparent electrode ITO layer 60.

The vertical light-emitting nanorod laser diode and a method of manufacturing the same described above and illustrated in the drawings are only embodiments for implementing the present invention, and should not be construed as limiting the technical idea of the present invention. The protection scope of the present invention is determined only by the matters described in the following patent claims, and embodiments that are improved and modified without departing from the gist of the present invention are considered to fall within the protection scope of the present invention as long as the embodiments are obvious to a person having ordinary skill in the art to which the present invention belongs.

1. A vertical light-emitting nanorod laser diode comprising:
a substrate including a plurality of nanoholes formed on an upper surface of the substrate;
a plurality of nanorod LED structures, each of the plurality of nanorod LED structures including thin films deposited on top of one another and disposed on each of the plurality of nanoholes to have a vertical length, and the thin films including a lower n-GaN layer, a quantum well active layer, a p-GaN layer, a tunnel junction layer, and an upper n-GaN layer, wherein the quantum well active layer, the p-GaN layer, and the tunnel junction layer are provided between the lower n-GaN layer and the upper n-GaN layer;
a passivation layer including a passivation material applied on the upper surface of the substrate to have a thickness covering the lower n-GaN layer, the quantum well active layer, the p-GaN layer, the tunnel junction layer, and a lower part of the upper n-GaN layer of each of the plurality of nanorod LED structures;
a lower metal electrode layer deposited on a lower surface of the substrate; and an ohmic metal electrode layer disposed on an upper part of the upper n-GaN layer of each of the nanorod LED structures,
wherein the tunnel junction layer is formed of one of Al, Au, In, Ga, MoS₂, graphene, AlN, InGaN, AlGaN, AlInGaN, and GaN.

2. The vertical light-emitting nanorod laser diode of claim 1, further comprising:
an indium tin oxide (ITO)-based transparent electrode ITO layer configured to replace the ohmic metal electrode layer or deposited on an upper portion of the ohmic metal electrode layer; and
an upper metal window electrode layer in which a window penetrated vertically is formed in a shape, a metal is deposited on a side end of the window, and the window is placed on the upper portion of the ohmic metal electrode layer or the transparent electrode ITO layer.

3. The vertical light-emitting nanorod laser diode of claim 1,
wherein each of the plurality of nanorod LED structures has: a structure in which the lower n-GaN layer, the quantum well active layer, the p-GaN layer, a p⁺-GaN layer, the tunnel junction layer, an n⁺-GaN layer, and the upper n-GaN layer are sequentially stacked; a structure in which the lower n-GaN layer, the quantum well active layer, the p-GaN layer, the tunnel junction layer, and the upper n-GaN layer are sequentially stacked; a structure in which the lower n-GaN layer, the tunnel junction layer, the p-GaN layer, the quantum well active layer, and the upper n-GaN layer are sequentially stacked; or a structure in which the lower n-GaN layer, the p⁺-GaN layer, the tunnel junction layer, the n⁺-GaN layer, the p-GaN layer, the quantum well active layer, and the upper n-GaN layer are sequentially stacked, and
wherein the passivation layer further covers the p⁺-GaN layer and the n⁺-GaN layer.

4. The vertical light-emitting nanorod laser diode of claim 1,
wherein the quantum well active layer includes a first nitride layer and a second nitride layer which are different from each other, has a structure in which the first nitride layer and the second nitride layer are interchangeably stacked in multiple layers, and
wherein the first nitride layer is formed of one of GaN, InN, AlGaN, AlInGaN, and AlN, and the second nitride layer is formed of one of InGaN, InN, AlGaN, AlInGaN, GaN, and AlN.

5. The vertical light-emitting nanorod laser diode according to claim 1,
wherein a full width at half maximum (FWHM) of an emission wavelength and a wavelength position are adjusted by changing cross-sectional shapes and cross-sectional sizes of the plurality of nanorod LED structures and intervals between the plurality of nanorod LED structures through changes in shapes, sizes, and arrangement patterns of the plurality of nanoholes.

6. A method of manufacturing a vertical light-emitting nanorod laser diode, the method comprising:
a nanohole patterning step of depositing a mask layer on an upper portion of a substrate, depositing a photoresist on the mask layer, and forming a plurality of nanoholes to have a shape, a size, and a pattern;
a nanorod forming step of depositing thin films to be stacked on top of one another and to be disposed on each of the plurality of nanoholes to have a length in a vertical direction and forming a plurality of nanorod LED structures, each of the plurality of nanorod LED structures including a lower n-GaN layer, a quantum well active layer, a p-GaN layer, a tunnel junction layer, and an upper n-GaN layer, wherein the quantum well active layer, the p-GaN layer, and the tunnel junction layer are disposed between the lower n-GaN layer and the upper n-GaN layer; a passivation layer forming step of forming a passivation layer by applying a passivation material on the upper portion of the substrate to have a thickness covering entirety of the plurality of nanorod LED structures;
a passivation layer etching step of etching an upper part of the upper n-GaN layer such that the upper part of the upper n-GaN layer is exposed;
a lower metal electrode layer depositing step of depositing a lower metal electrode layer on a lower surface of the substrate; and
an ohmic metal electrode layer depositing step of placing an ohmic metal electrode on the upper part of the upper n-GaN layer,
wherein the tunnel junction layer in the nanorod forming step is formed of one of Al, Au, In, Ga, MoS₂, graphene, AlN, InGaN, AlGaN, AlInGaN, and GaN.

7. The method of claim 6, further comprising:
a transparent electrode ITO layer depositing step of replacing the ohmic metal electrode layer or depositing an indium tin oxide (ITO)-based transparent electrode ITO layer on an upper portion of the ohmic metal electrode layer; and
an upper metal window electrode layer depositing step of depositing an upper metal window electrode layer in which a window penetrated vertically is formed in a preset shape and metal is deposited on a side end of the window such that the window is placed on the upper portion of the ohmic metal electrode layer or the transparent electrode ITO layer.
